(19) United States
(12) Patent Application Publication
(10) Pub. No.: US 2026/0122730 A1
(43) Pub. Date: Apr. 30, 2026

(54) CARBON NANOTUBE MICRO-HEATING CHIP AND PREPARATION METHOD THEREOF

(71) Applicants: Tsinghua University, Beijing (CN); HON HAI PRECISION INDUSTRY CO., LTD., New Taipei (TW)

(72) Inventors: JIE ZHAO, Beijing (CN); LIANG LIANG, Beijing (CN); ZHONG-YUAN ZHAO, Beijing (CN); QUN-QING LI, Beijing (CN); YANG WEI, Beijing (CN); SHOU-SHAN FAN, Beijing (CN)

(21) Appl. No.: 19/177,822

(22) Filed: Apr. 14, 2025

(30) Foreign Application Priority Data
Apr. 19, 2024 (CN) 202410472511.7

(51) Int. Cl. H05B 3/14; H01J 37/26; H05B 3/26

(52) U.S. Cl. CPC H05B 3/145; H01J 37/261; H05B 3/265; H05B 2203/017

(57) ABSTRACT

A carbon nanotube micro-heating chip, comprising: a substrate comprising a first surface and a second surface opposite to each other, wherein the substrate defines a through hole getting through the first surface and the second surface; an insulating layer located on the first surface of the substrate and suspended on the through hole to form a window, a plurality of grooves are defined in the window to form a sample pool; a first carbon nanotube layer and a second carbon nanotube layer arranged at intervals in the window and exposed out from the sample pool; and a metal thermometer arranged in the window between the first carbon nanotube layer and the second carbon nanotube layer and being configured to measure a temperature of a heated area.

### CROSS-REFERENCE TO RELATED APPLICATIONS

This application claims all benefits accruing under 35 U.S.C. § 119 from China Patent Application No. 202410472511.7, filed on Apr. 19, 2024, in the China National Intellectual Property Administration, the contents of which are hereby incorporated by reference.

### FIELD

The disclosure relates to a carbon nanotube micro-heating chip and a preparation method thereof, and in particular to a carbon nanotube micro-heating chip applied to an in-situ transmission electron microscope and a preparation method thereof.

### BACKGROUND

The combination of microelectromechanical systems (MEMS) and transmission electron microscopes (TEM) has made great progress in in-situ TEM characterization. TEM has ultra-high spatial resolution for the observation of microscopic dynamic processes. It is well known that a transmission electron microscope corrected for spherical aberration can even achieve a spatial resolution of sub-angstrom. A variety of in-situ TEM techniques have been developed, including in-situ heating, in-situ biasing, in-situ stressing, in-situ ventilation, etc. The main functional component of the TEM microheater chip is the electron transparent window, which is usually formed by depositing a metal resistor wire on a suspended silicon nitride (SiNₓ) film, and the metal resistor layer and the SiNₓ film form a double-layer structure. This microheater has an ultra-low heat capacity, can achieve low power consumption and fast and precise control of temperature. However, the different thermal expansion coefficients of the metal resistor layer and the SiNₓ film cause the electron transparent window to expand and bulge at high temperatures, so that the sample will move out of the best focus. Therefore, the expansion of the electron transparent window will seriously affect the dynamic observation of the sample during TEM characterization.

### BRIEF DESCRIPTION OF THE DRAWINGS

Implementations of the present technology will now be described, by way of example only, with reference to the attached FIG.s, wherein:

FIG. 1 is a schematic diagram of a structure of a carbon nanotube micro-heating chip provided in a first embodiment of the present disclosure.

FIG. 2 is a schematic diagram of the structure of the carbon nanotube micro-heating chip provided in the first embodiment of the present disclosure and a partial enlarged view.

FIG. 3 is a stereoscopic image of the carbon nanotube micro-heating chip provided in the first embodiment of the present disclosure.

FIG. 4 is an optical microscope image of an SiNₓ window in the carbon nanotube micro-heating chip provided in the first embodiment of the present disclosure.

FIG. 5 is an optical microscope image of a sample pool in the carbon nanotube micro-heating chip provided in the first embodiment of the present disclosure.

FIG. 6 shows Raman characteristics of a carbon nanotube layer before and after patterning.

FIG. 7 is a schematic diagram of a temperature distribution of six (6) SiNₓ windows taken by an infrared radiometer at a same power.

FIG. 8 shows a current-voltage (I-V) characteristic curve of the carbon nanotube micro-heating chip.

FIG. 9 shows an incandescent light spectrum of the carbon nanotube micro-heating chip under different heating voltages.

FIG. 10 is a photograph of an incandescent light generated by the SiNₓ window at high temperature, taken by a Canon camera with a macro lens.

FIG. 11 shows a heating process of the carbon nanotube micro-heating chip at 800° C.

FIG. 12 shows a cooling process of the carbon nanotube micro-heating chip at 800° C.

FIG. 13 shows a temperature response of the carbon nanotube micro-heating chip at 800° C. when the applied frequency is 2 Hz.

FIG. 14 shows a temperature response of the carbon nanotube micro-heating chip at 800° C. when the applied frequency is 5 Hz.

FIG. 15 shows a temperature response of the carbon nanotube micro-heating chip at 800° C. when the applied frequency is 10 Hz.

FIG. 16 shows a temperature response of the carbon nanotube micro-heating chip at 800° C. when the applied frequency is 40 Hz.

FIG. 17 is a TEM image of an isocenter height of gold particles taken at room temperature with a highest resolution.

FIG. 18 is a TEM image of gold particles heated to 800° C. in situ without focus adjustment.

FIG. 19 is a TEM image of gold particles heated to 800° C., with a z height change of about 100 nm, wherein an insert in FIG. 19 is an FFT image of each TEM image, with a scale of 10 nm for the TEM image and 5 nm−1 for the FFT image.

FIG. 20 is a TEM image of tin particles at room temperature.

FIG. 21 is a Fourier transform image of tin particles at room temperature.

FIG. 22 is a TEM image of tin particles at 240° C.

FIG. 23 is a Fourier transform image of tin particles at 240° C.

FIG. 24 is a process flow chart of a method for preparing a carbon nanotube micro-heating chip provided in a specific embodiment of the present disclosure.

### DETAILED DESCRIPTION

The disclosure is illustrated by way of example and not by way of limitation in the FIG.s of the accompanying drawings in which like references indicate similar elements. It should be noted that references to “another,” “an,” or “one” embodiment in this disclosure are not necessarily to the same embodiment, and such references mean “at least one.”

It will be appreciated that for simplicity and clarity of illustration, where appropriate, reference numerals have been repeated among the different FIG.S to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts have been exaggerated to illustrate details and features of the present disclosure better.

Several definitions that apply throughout this disclosure will now be presented.

The term “substantially” is defined to be essentially conforming to the particular dimension, shape, or other feature which is described, such that the component need not be exactly or strictly conforming to such a feature. The term “comprise,” when utilized, means “comprise, but not necessarily limited to”; it specifically indicates open-ended inclusion or membership in the so-described combination, group, series, and the like. The term of “first”, “second” and the like, are only used for description purposes, and should not be understood as indicating or implying their relative importance or implying the number of indicated technical features. Thus, the features defined as “first”, “second” and the like expressly or implicitly comprise at least one of the features. The term of “multiple times” means at least two times, such as two times, three times, etc., unless otherwise expressly and specifically defined.

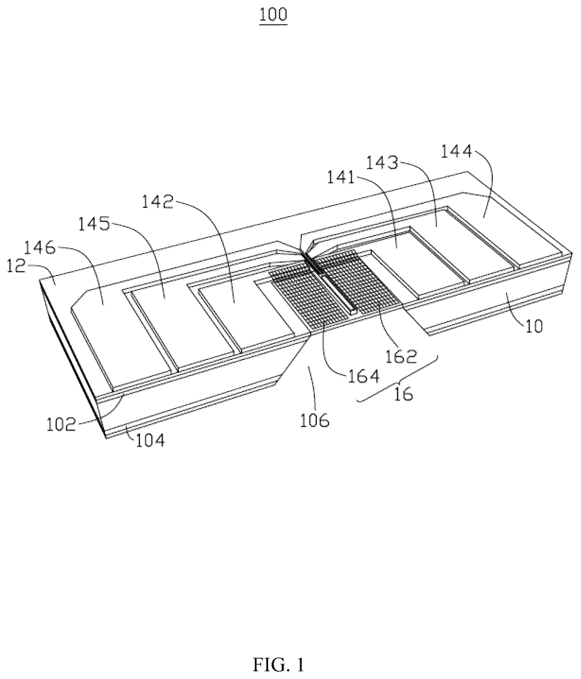

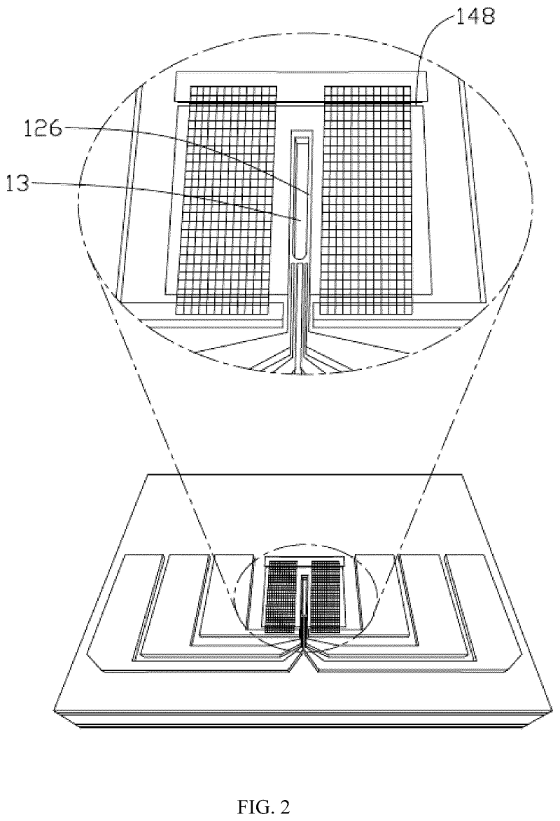

Referring to FIG. 1 and FIG. 2, an embodiment of the present disclosure provides a carbon nanotube micro-heating chip 100, which comprises a substrate 10, an insulating layer 12, a carbon nanotube layer 16, a metal thermometer 13 and a plurality of electrodes.

The substrate 10 has a first surface 102 and a second surface 104 opposite to each other, and the substrate 10 is provided with a through hole 106, which runs from the first surface 102 of the substrate 10 to the second surface 104 of the substrate 10.

A material of the substrate 10 can be a conductor, a semiconductor, or an insulating material. Specifically, the material of the substrate 10 can be gallium nitride, gallium arsenide, sapphire, aluminum oxide, magnesium oxide, silicon, silicon dioxide, silicon nitride, quartz or glass, etc. The material of the substrate 10 can also be a flexible material such as polyethylene terephthalate (PET) and polyimide (PI). Further, the material of the substrate 10 can also be a doped semiconductor material, such as P-type gallium nitride, N-type gallium nitride, etc. The size, thickness and shape of the substrate 10 are not limited and can be selected according to actual needs. In this embodiment, the substrate 10 is a silicon wafer with a silicon oxide thickness of 200 nm.

The insulating layer 12 is located on the first surface 102 of the substrate 10, and the insulating layer 12 is suspended at the through hole 106 to form a window. A plurality of grooves 126 are provided on the insulating layer located at the through hole 106 as a sample pool for carrying samples.

A material of the insulating layer 12 is silicon nitride (SiNₓ), silicon carbide, etc. A thickness of the insulating layer 12 is relatively thin and can be transparent to electrons. The thickness of the insulating layer 12 is 50 nm to 200 nm. In this embodiment, the insulating layer 12 is a silicon nitride (SiNₓ) film with a thickness of 200 nm.

A shape of the groove 126 is not limited, and the thickness of the insulating layer at the bottom of the groove is 1 nm to 100 nm. Preferably, the thickness of the insulating layer at the bottom of the groove is 10 nm, 20 nm, 30 nm, 40 nm or 50 nm. Since the groove 126 is etched on the insulating layer 12, the thickness of the insulating layer at the bottom of the groove is thinner, thereby ensuring that the thickness of the sample pool is thin enough to allow electrons to pass through, or transparent to electrons. In this embodiment, the diameter of the groove is 3 μm, the thickness of the insulating layer at the bottom of the groove is 50 nm, and the groove 126 serves as a sample pool for carrying samples.

The carbon nanotube layer 16 is located on a surface of the insulating layer 12 away from the substrate 10, and the carbon nanotube layer 16 covers the window and exposes the sample pool. In this embodiment, the carbon nanotube layer 16 is only located on the window, and the carbon nanotube layer 16 comprise a first carbon nanotube layer 162 and a second carbon nanotube layer 164, which are respectively arranged on both sides of the sample pool, and the first carbon nanotube layer 162 and the second carbon nanotube layer 164 are electrically connected through the seventh electrode 148.

Each of the carbon nanotube layers 16 comprises at least one layer of super-aligned carbon nanotube film (SACNT), which is a carbon nanotube film obtained by pulling from a super-aligned carbon nanotube array. The super-aligned carbon nanotube film is composed of a plurality of carbon nanotubes that are preferentially oriented in the same direction and arranged parallel to the surface of the super-aligned carbon nanotube film, and the carbon nanotubes are connected end to end by van der Waals forces.

When the carbon nanotube layer 16 comprises multiple layers of super-aligned carbon nanotube film, the multiple layers of super-aligned carbon nanotube film are stacked on each other, and a cross angle α is formed between the preferentially oriented carbon nanotubes in two adjacent layers of super-aligned carbon nanotube film, and α is greater than or equal to 0 degrees and less than or equal to 90 degrees (0°≤α≤90°).

In this embodiment, the carbon nanotube layer 16 comprises two layers of super-aligned carbon nanotube films, which are orthogonally arranged on the surface of the insulating layer away from the substrate 10, that is, the extension directions of the carbon nanotubes in the two layers of super-aligned carbon nanotube films are perpendicular to each other.

The carbon nanotube micro-heating chip 100 comprises a metal thermometer 13, which is located in a gap between the first carbon nanotube layer 162 and the second carbon nanotube layer 164. In this embodiment, the metal thermometer 13 is a platinum thermometer.

The multiple electrodes are located on the surface of the insulating layer 12 away from the substrate 10. The multiple electrodes include a first electrode 141, a second electrode 142, a third electrode 143, a fourth electrode 144, a fifth electrode 145, a sixth electrode 146 and a seventh electrode 148. The first electrode 141 is located on the side of the first carbon nanotube layer 162 away from the sample pool and is electrically connected to the first carbon nanotube layer 162. The second electrode 142 is located on the side of the second carbon nanotube layer 164 away from the sample pool and is electrically connected to the second carbon nanotube layer 164. The third electrode 143 and the fourth electrode 144 are located on the side of the first electrode 141 away from the first carbon nanotube layer 162, and one end of the third electrode 143 and the fourth electrode 144 are electrically connected to the metal thermometer respectively. The fifth electrode 145 and the sixth electrode 146 are located on the side of the second electrode 142 away from the second carbon nanotube layer 164, and one end of the fifth electrode 145 and the sixth electrode 146 are electrically connected to the metal thermometer respectively. One end of the seventh electrode 148 is electrically connected to the first carbon nanotube layer 162, and the other end is electrically connected to the second carbon nanotube layer 164. The seventh electrode 148 connects the first carbon nanotube layer 162 and the second carbon nanotube layer 164 in series.

Materials of the first electrode 141 to the seventh electrode 148 have good electrical conductivity. Specifically, the materials of the first electrode 141 to the seventh electrode 148 can be conductive materials such as metal, alloy, indium tin oxide (ITO), antimony tin oxide (ATO), conductive silver paste, conductive polymer and metallic carbon nanotube film. In this embodiment, the first electrode 141 to the seventh electrode 148 are Cr/Pt electrodes prepared on a silicon nitride (SiNₓ) film by electron beam evaporation. The Cr/Pt electrode is first deposited with 5 nm thick Cr (chromium) on the silicon nitride (SiNₓ) film, and then 50 nm thick Pt (platinum) is deposited on Cr (chromium).

The carbon nanotube micro-heating chip 100 also comprises the barrier layer 18, which is located on the second surface 104 of the substrate 10. The barrier layer 18 is provided with an opening for preparing a through hole 106, and the opening corresponds to the through hole 106 one by one. The insulating layer 12 is exposed at the opening and the through hole 106 to form a suspended window.

The carbon nanotube micro-heating chip 100 installed on the TEM platform is connected to the external circuit through the first electrode 141 to the sixth electrode 146. The first carbon nanotube layer 162 and the second carbon nanotube layer 164 can be powered through the first electrode 141 and the second electrode 142 to heat the first carbon nanotube layer 162 and the second carbon nanotube layer 164. The third electrode 143, the fourth electrode 144, the fifth electrode 145, and the sixth electrode 146 are electrically connected to the platinum thermometer. A constant current is passed through the third electrode 143 and the fifth electrode 145 to the platinum thermometer, and then the voltage of the platinum thermometer is measured through the fourth electrode 144 and the sixth electrode 146, and its resistance is calculated. The temperature is monitored according to the resistance of the platinum thermometer, and then the input power to the first carbon nanotube layer 162 and the second carbon nanotube layer 164 is adjusted according to the required temperature.

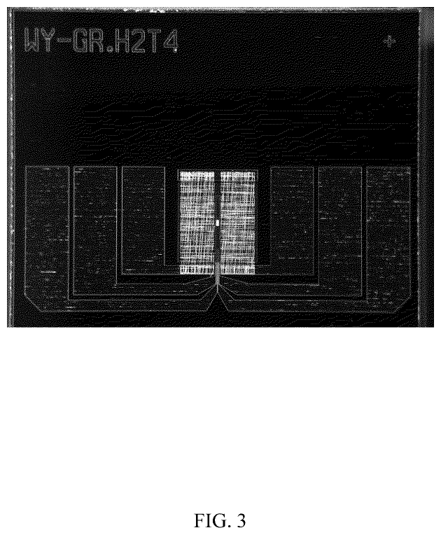

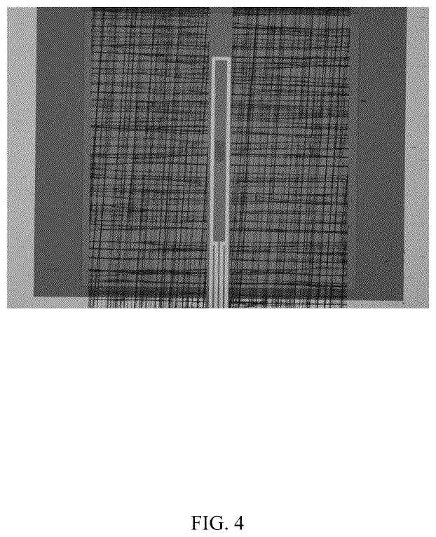

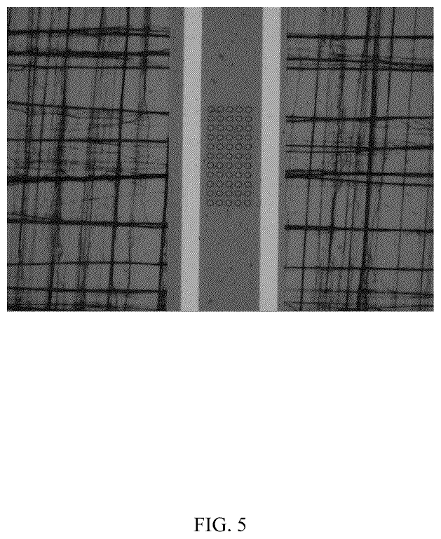

Please refer to FIGS. 3-5. FIG. 3 shows a stereo microscope image of the carbon nanotube micro-heating chip, while FIGS. 4-5 provide optical microscope images of the SiNₓ window and the sample pool, respectively. The carbon nanotube film on the SiNₓ window has a network structure consisting of hundreds of carbon nanotube bundles. Each carbon nanotube bundle is formed by merging a single carbon nanotube during the manufacturing process. The sample pool is a circular groove array with a groove diameter of 3 microns and a SiNₓ thickness of about 50 nanometers at the groove, ensuring high electron transparency for TEM observation.

The following is a performance characterization of the carbon nanotube micro-heating chip 100.

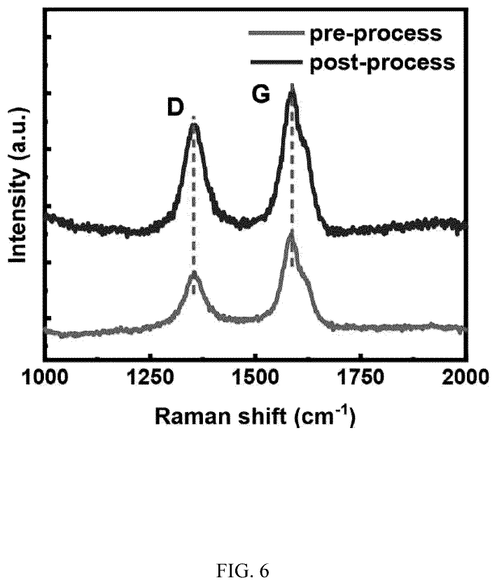

FIG. 6 shows a Raman characterization of the carbon nanotube layer before and after patterning. As shown in FIG. 6, in the Raman spectrum, the G peak (approximately at 1580 cm⁻¹) indicates lattice vibration, while the D peak (approximately at 1350 cm⁻¹) indicates impurities and defects. The intensity of the D peak is generally used to evaluate the quality and purity of carbon nanotubes. The weaker the D peak intensity, the higher the quality and purity. As shown in the green solid line and blue solid line in FIG. 6, the G peak intensity is higher than the D peak intensity, indicating that the carbon nanotubes on the chip have higher quality. All micro-nano processing and super-aligned carbon nanotube film laying are carried out on 4-inch wafers, and the processed wafers are cut into individual CNT micro-heater chips with a diamond saw. One 4-inch wafer can produce hundreds of carbon nanotube micro-heating chips.

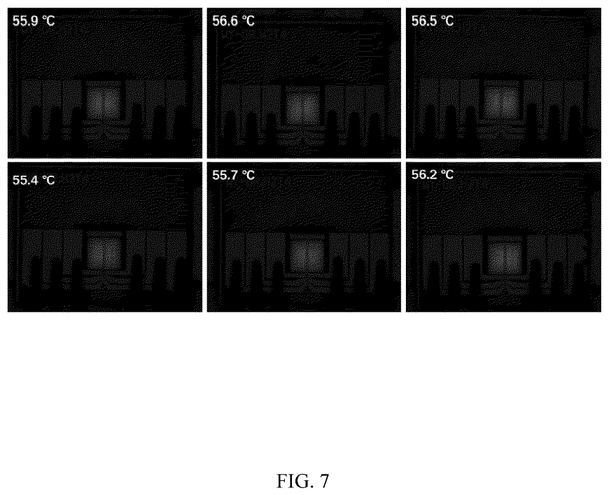

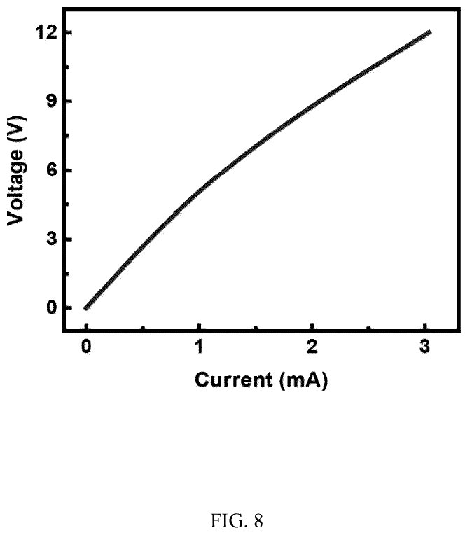

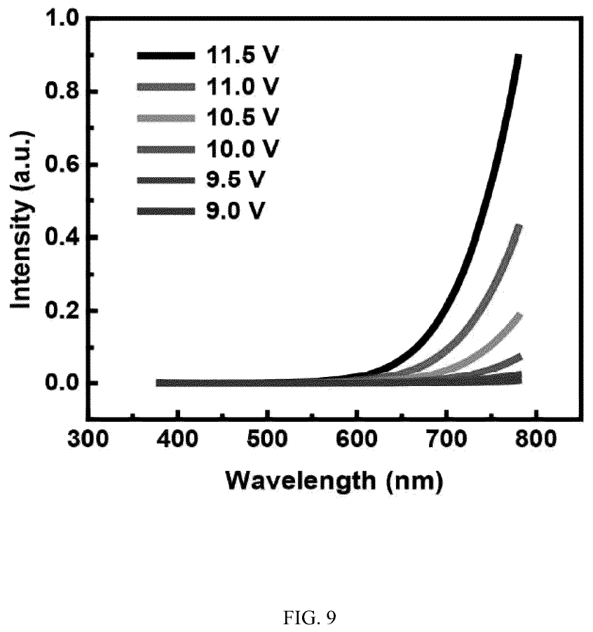

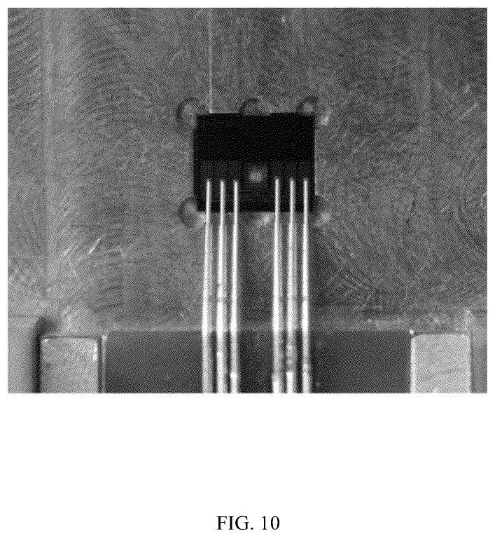

The chips produced from the same wafer have good consistency. FIG. 7 shows infrared images of six of the chips, which are heated with the same heating power. The temperature difference between them does not exceed 2.1° C., and the temperature distribution of all films also shows a high degree of consistency. The high temperature state of the carbon nanotube micro-heating chip was further studied under dynamic vacuum conditions. FIG. 8 plots the current-voltage (I-V) characteristics of the carbon nanotube micro-heating chip under vacuum conditions. When the voltage applied to the carbon nanotube layer exceeds the threshold, visible incandescent light can be observed in the thermal window, and its brightness increases with the increase of heating power. FIG. 9 shows the incandescent light spectrum of the carbon nanotube micro-heating chip under different heating voltages. FIG. 10 shows the photo of the carbon nanotube micro-heating chip emitting incandescent light taken by a camera. The infrared image and optical image confirm that the use of super-aligned carbon nanotube layer as the Joule heating element of the micro-heating chip is an effective design.

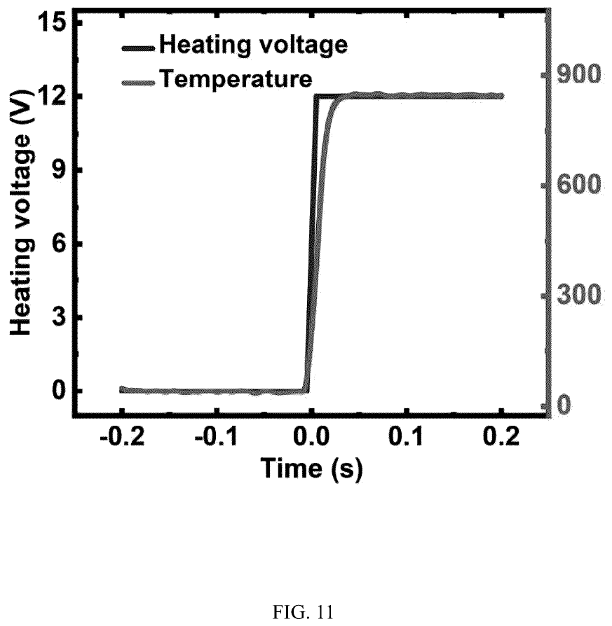

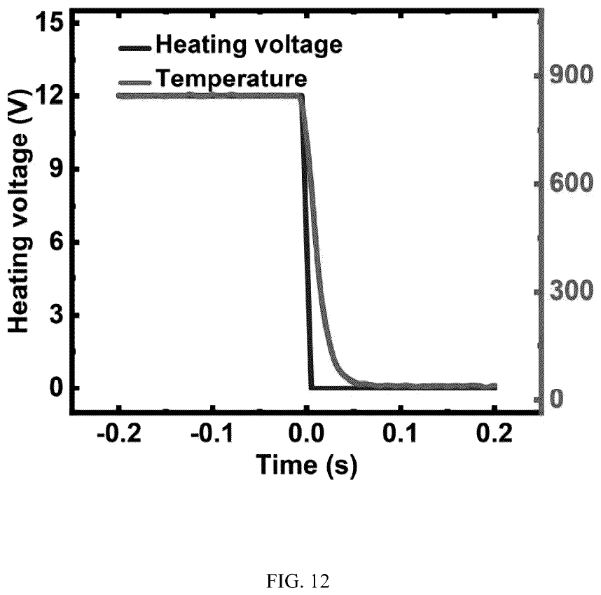

FIG. 11 and FIG. 12 respectively show the heating and cooling process of the carbon nanotube micro-heating chip. The carbon nanotube micro-heating chip is heated to 800° C. by a 12 V DC bias and then cooled. The rise time refers to the duration of the temperature change from 10% to 90%, while the cooling time refers to the duration of the temperature change from 90% to 10%. According to the measurement, the rise time and cooling time are 16.07±0.21 milliseconds and 26.34±0.29 milliseconds, respectively. By numerically derivation of the temperature-time curve, the maximum temperature change rate of the carbon nanotube micro-heating chip is as high as 8×10⁴° C./s. The heating time of the conventional structure heater of the metal resistor layer is between 33 and 81 milliseconds, and the maximum temperature change rate is generally around 104° C./s. It can be seen that the carbon nanotube micro-heating chip performs well in fast high-temperature response.

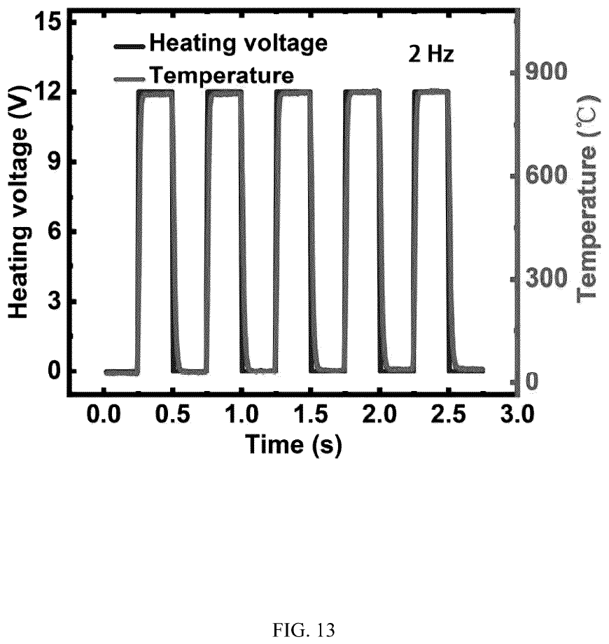

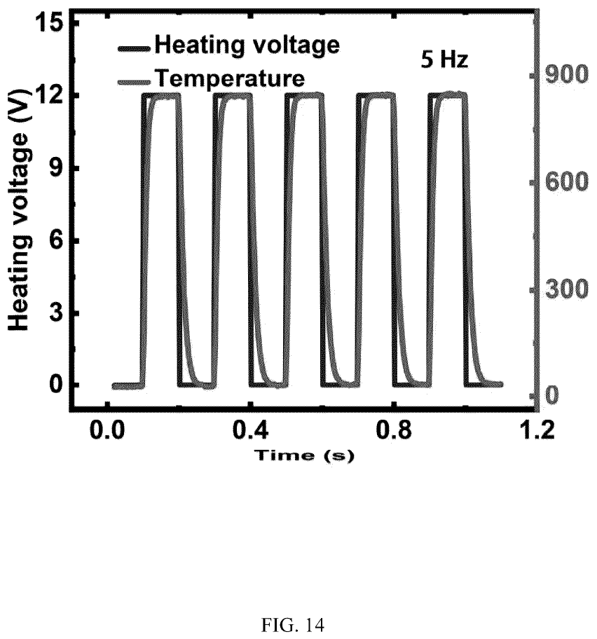

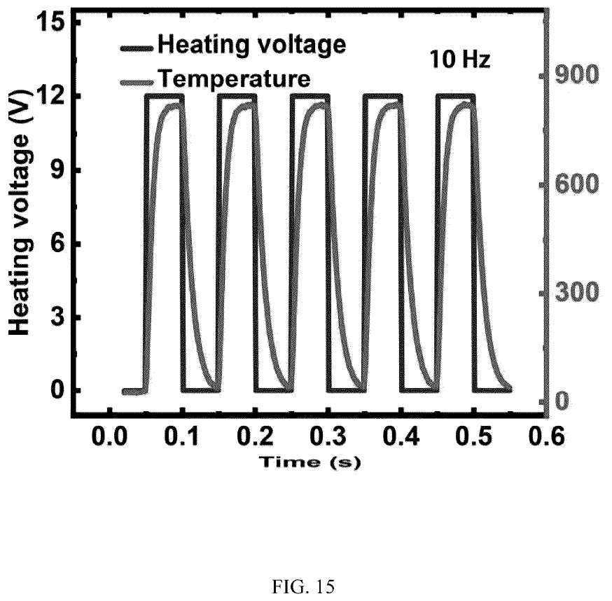

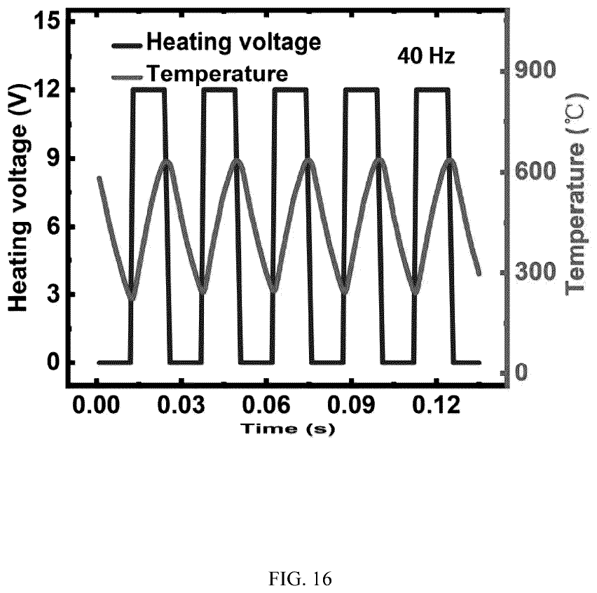

In order to present a fast high-temperature response, the frequency response of the carbon nanotube micro-heating chip was further studied. As shown in FIG. 13 to FIG. 14, pulse square wave signals of different frequencies were applied, and the duty cycle was fixed at 50%. In FIG. 13, at 2 Hz, the temperature signal and the heating signal basically coincided (FIG. 7c). In FIG. 14, starting from 5 Hz, the temperature waveform showed a trend of transformation to a triangular wave. In FIG. 15, as the frequency increased, the waveform continued to change, and the amplitude of the response signal decreased. Nevertheless, as shown in FIG. 16, the carbon nanotube micro-heating chip still had a considerable response to the 40 Hz input signal. These experiments verified the fast high-temperature response capability of the manufactured carbon nanotube micro-heating chip, which can effectively meet the requirements of fast temperature control. The fast high-temperature response can be attributed to the micro/nanostructure and tubular structure of CNT. The micro/nanostructure greatly reduces the mass and heat capacity. The carbon nanotube layer has a large specific surface area and can dissipate heat quickly.

Gold (Au) nanoparticles were deposited on the sample pool of the carbon nanotube micro-heating chip 100, and the sample pool was imaged under TEM to observe the deformation (expansion) of the sample pool.

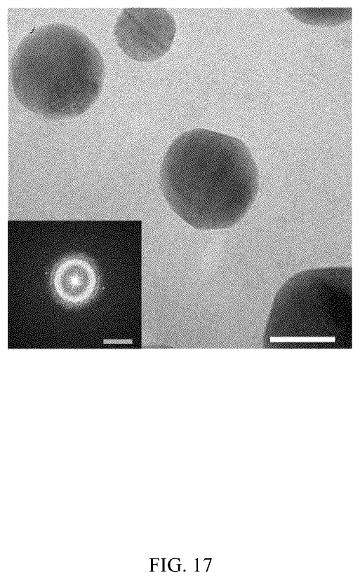

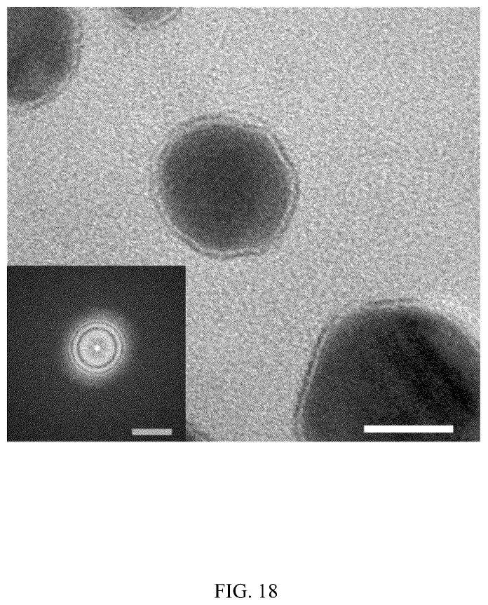

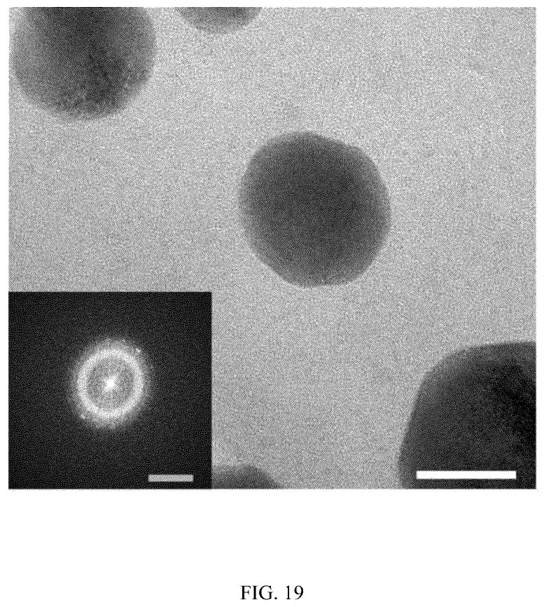

The carbon nanotube micro-heating chip was mounted on a DENS holder and TEM observation was performed using a FEI Tecnai F20 at a voltage of 200 kV. Initially, the TEM focused image of the gold particles captured at room temperature showed an observable gold lattice, as shown in FIG. 17. As the temperature increased, the Joule heating film deformed vertically, resulting in overfocus, as shown in FIG. 18. By adjusting the condenser defocus, the image with the best resolution can be regained, as shown in FIG. 19 (FIG. 8, c). This process is also evidenced by the Bragg spots restored in the Fourier transform (FFT) graph. The change in z height represents the bulge of the sample pool, and the bulge measured at 800° C. was 100 nm. The sample pool is about 20 μm wide, accounting for less than 3% of the 730 μm wide SiNx membrane. In addition, the profile of the raised membrane is dome-shaped, with the smallest gradient at the sample pool. Therefore, at 800° C., the change in deformation height in the sample pool should not exceed 3 nm. These results show that the performance of the CNT microheating chip is superior to that of traditional MEMS heater chips, which usually have micron-scale protrusions at similar temperatures. The comparison of the CNT microheating chip with other heater chips reported in the literature is shown in Table 1. The reduction of the protrusion effect can effectively solve the problem of defocusing caused by deformation when performing in situ TEM observation of dynamic processes.

TABLE 1
Deformation comparison

| Heating material | Temperature (° C.) | Deformation (μm) |
|---|---|---|
| SACNT | 800 | 0.1 |
| Mo | 691 | 7.04 |
| Pt/Ta | 622 | 11 |
| Ir/Pt/Ta | 665 | 11 |
| Pt | 414 | 0.5 |
| | 600 | 6 |
| | 500 | 0.45 |
| W | 750 | 14.5 |

The use of carbon nanotube layers can suppress the bulge of the film. In conventional MEMS heaters, the film window has a typical double-layer structure, that is, a metal resistor layer is deposited on a SiNx independent film. During the thin film deposition process, in order to improve the quality of the resistor layer, an ultra-thin adhesion layer (such as platinum or chromium) is usually deposited first, which can chemically bond with the substrate below and the resistor layer above. Therefore, there is a strong adhesion between the resistor layer and the SiNx film. When the micro heater is powered on for heating, the mismatched coefficients of thermal expansion (CTE, 2.1-3.6 for SiNx, and greater than 6 for metals including Pt, Au and Mo) will generate huge interfacial stress. The generated stress must be released through the protrusions. However, in the carbon nanotube micro-heating chip, the metal resistance wire has been replaced by the carbon nanotube layer. Since there are no dangling bonds on the surface of the carbon nanotubes, the individual carbon nanotubes in the carbon nanotube layer are assembled together through inter-tube van der Waals force interactions. The carbon nanotube layer is also adhered to the silicon nitride (SiNX) film by weak van der Waals forces. In addition, the tubular structure and mesh morphology effectively reduce the contact area between the carbon nanotube layer and the silicon nitride (SiNX) film. Therefore, the contact area between the carbon nanotubes and silicon nitride (SiNX) is greatly reduced.

The interfacial stress between the carbon nanotube/silicon nitride film and the carbon nanotube/silicon nitride film can be effectively minimized. Therefore, compared with the conventional MEMS heating chip, the bulging phenomenon of the carbon nanotube/silicon nitride film is significantly suppressed. Therefore, the carbon nanotube layer can effectively reduce the bulging effect and improve the performance of the micro heater.

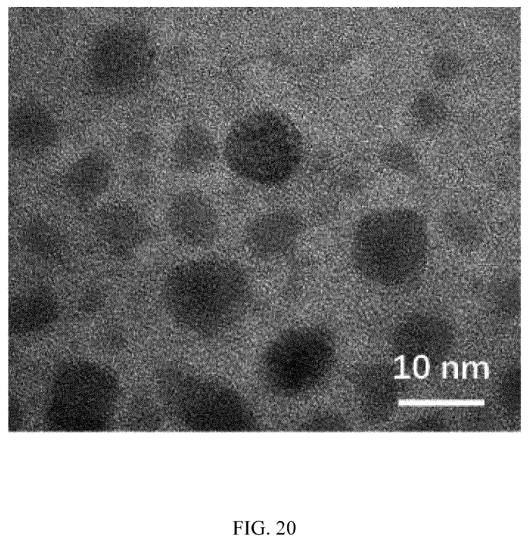

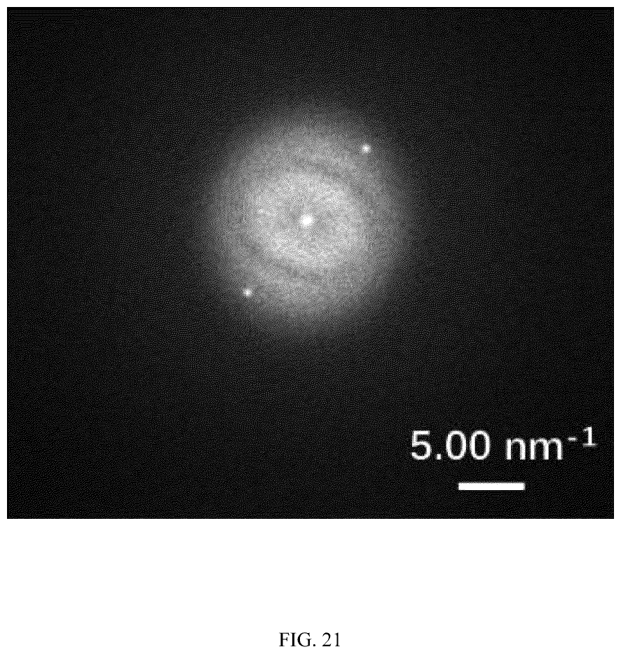

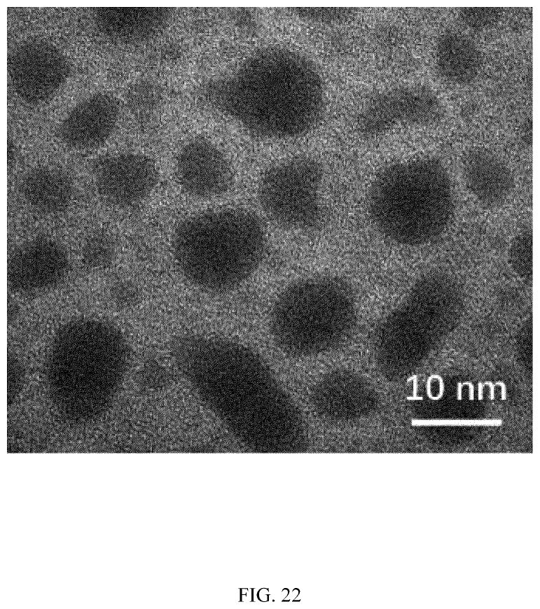

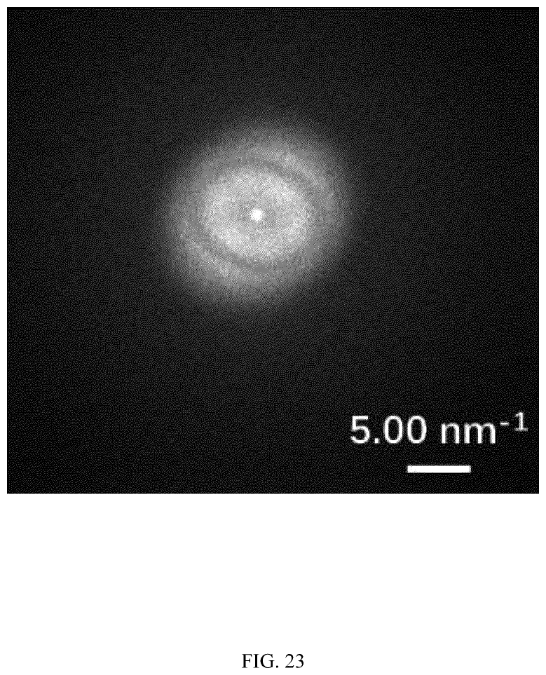

The melting process of tin (Sn) nanoparticles was observed in situ through the carbon nanotube micro-heating chip 100. Sn nanoparticles were sputtered onto the film from the back of the carbon nanotube micro-heating chip. The sample was mounted on the DENS Lightning TEM platform. The in situ experiment was conducted under a FEI Tecnai F20 microscope. The comparison of FIG. 20 to FIG. 23 shows the TEM images of the tin particles before and after melting and the corresponding FFT. FIG. 20 and FIG. 21 show the TEM image and FFT pattern of the tin nanoparticles at room temperature, which show the crystalline structure of tin. As shown in FIG. 22 and FIG. 23, when the temperature control system sets the sample temperature to 240° C., the TEM image and FFT pattern captured at the same position no longer show any lattice fringes or Bragg spots, respectively. The disappearance of the lattice indicates that Joule heating induces the solid-liquid phase transition of Sn. FIG. 20 to FIG. 23 show that the carbon nanotube micro-heating chip 100 can effectively solve the thermodynamic process in the in-situ TEM observation.

The carbon nanotube layer of this embodiment is an independent CNT network composed of neatly arranged CNTs with a thickness of about 100 nm. Therefore, the carbon nanotube layer has an ultra-small heat capacity per unit area (HCPUA) of about 7.7×10⁻³ J/m²-K. Due to its tubular structure and the strong carbon sp² bonds therein, the CNT material also has high thermal stability. Moreover, the independent CNT structure can even be heated to 2200 K. The smaller heat capacity and higher constant temperature make the carbon nanotube micro-heating chip perform better than the traditional metal resistance wire heating chip. In addition, since carbon nanotubes have high electron transparency, the carbon nanotube micro-heating chip can adopt a full-window heating strategy. Full-window heating greatly reduces the temperature gradient and improves the temperature uniformity in the central area where the sample pool is located, which can be confirmed by infrared images.

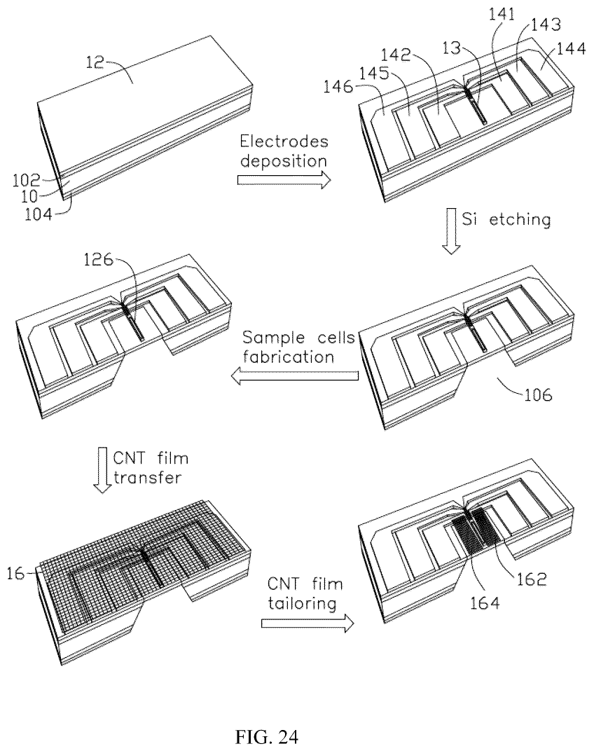

Please refer to FIG. 24, one embodiment of the present disclosure further provides a method for preparing a carbon nanotube micro-heating chip 100, which comprises the following steps:
S1, providing a substrate 10 comprising a first surface 102 and a second surface 104;
S2, applying an insulating layer 12 on the first surface 102;
S3, setting seven electrodes and a metal thermometer 13 on a surface of the insulating layer 12 away from the substrate 10, the seven electrodes are named first electrode 141, second electrode 142, third electrode 143, fourth electrode 144, fifth electrode 145, sixth electrode 146 and seventh electrode 148 in sequence, one end of the third electrode 143 and the fourth electrode 144 are respectively electrically connected to the metal thermometer, and one end of the fifth electrode 145 and the sixth electrode 146 are respectively electrically connected to the metal thermometer;
S4: forming a thorough hole 106 in the substrate 10 getting through the first surface 102 and the second surface 104, wherein the insulating layer 12 covers the trough hole 106, a part of the insulating layer 12 suspends above the trough hole 106 is defined as a window (not labeled);
S5, forming a plurality of grooves 126 in the window as a sample pool for carrying samples, wherein the first carbon nanotube layer 162 and the second carbon nanotube layer 164 are covered in the window, and the plurality of grooves 126 for carrying samples is arranged between the first carbon nanotube layer 162 and the second carbon nanotube layer 164, and the first carbon nanotube layer 162 and the second carbon nanotube layer 164 are electrically connected through the seventh electrode 148, the first electrode 141 is electrically connected to the first carbon nanotube layer 162, and the second electrode 142 is electrically connected to the second carbon nanotube layer 164.

In step S1, a material of the substrate 10 can be a conductor, a semiconductor or an insulating material. Specifically, the material of the substrate 10 can be gallium nitride, gallium arsenide, sapphire, aluminum oxide, magnesium oxide, silicon, silicon dioxide, silicon nitride, quartz or glass, etc. The material of the substrate 10 can also be a flexible material such as polyethylene terephthalate (PET) and polyimide (PI). Further, the material of the substrate 10 can also be a doped semiconductor material, such as P-type gallium nitride, N-type gallium nitride, etc. The size, thickness and shape of the substrate 10 are not limited and can be selected according to actual needs.

In step S2, a material of the insulating layer 12 is silicon nitride (SiNₓ), silicon carbide, etc., and the thickness of the insulating layer 12 is relatively thin and can be transparent to electrons. The thickness of the insulating layer 12 is ranged from 50 nm to 200 nm. Preferably, the insulating layer 12 is a silicon nitride (SiNₓ) film. In a specific embodiment, the insulating layer 12 is a silicon nitride (SiNₓ) film with a thickness of 200 nm.

In step S3, the material of the first electrode 141 to the seventh electrode 148 has good conductivity. Specifically, the material of the first electrode 141 to the seventh electrode 148 can be a conductive material such as metal, alloy, indium tin oxide (ITO), antimony tin oxide (ATO), conductive silver paste, conductive polymer, and metallic carbon nanotube film. Depending on the type of material forming the first electrode 141 to the seventh electrode 148, different methods can be used to form the first electrode 141 to the seventh electrode 148. Specifically, when the material of the first electrode 141 to the seventh electrode 148 is metal, alloy, ITO or ATO, the first electrode 141 to the seventh electrode 148 can be formed by evaporation, sputtering, deposition, masking and etching. When the material of the first electrode 141 to the seventh electrode 148 is a conductive silver paste, a conductive polymer or a carbon nanotube film, the conductive silver paste or the carbon nanotube film can be applied or adhered to the surface of the insulating layer 12 away from the substrate 10 by printing or direct adhesion to form the first electrode 141 to the seventh electrode 148. The thickness of the first electrode 141 to the seventh electrode 148 is 0.5 nanometers to 100 micrometers. The metal thermometer can be composed of a metal material whose resistivity changes linearly with temperature, such as molybdenum and platinum.

In this embodiment, the first electrode 141 to the seventh electrode 148 is a Cr/Pt electrode formed by electron beam evaporation, and the Cr/Pt electrode is a 50 nm thick Pt (platinum) deposited on a 5 nm thick Cr (chromium). The metal thermometer is a platinum thermometer.

In step S4, the method of forming the through hole 106 is not limited, such as plasma etching, laser and other methods. This embodiment provides a method for forming the through hole 106, which specifically comprise the following steps:
S41, providing a barrier layer 18 on the second surface 104 of the substrate 10;
S42, etching an opening on the barrier layer 18, and the second surface 104 of the substrate 10 is exposed through the opening;
S43, placing the substrate 10 and the etched barrier layer 18 in an etching liquid, or the etching liquid is dripped into the opening, the etching liquid contacts the substrate 10 through the opening, and the etching liquid reacts chemically with the substrate 10, thereby forming the through hole 106 on the substrate 10, the opening and the through hole 106 correspond one to one, a part of the insulating layer 12 is suspended at the opening and the through hole 106, and the part of the insulating layer 12 is exposed through the opening and the through hole 106 to form a window.

In step S41, the material of the barrier layer 18 does not react chemically with the etching liquid. In a specific embodiment, the substrate 10 is a silicon wafer having a layer of silicon dioxide on both the first surface 102 and the second surface 104, and the barrier layer 18 is a silicon nitride (SiNx) film.

In step S42, the method for etching the opening is photolithography, plasma etching, etc.

In step S43, the etching liquid does not react with the insulating layer 12 and the seven electrodes, but only chemically reacts with the substrate 10, thereby forming the through hole 106 on the substrate 10. In a specific embodiment, the substrate 10 is a silicon wafer having a layer of silicon dioxide on both the first surface 102 and the second surface 104, and the etching liquid is a potassium hydroxide (KOH) solution.

In step S5, the method of providing a plurality of the grooves 126 on the insulating layer 12 to form a sample pool is not limited, for example, a method of first patterning photolithography and then gas plasma etching is adopted. Specifically, a mask is used to cover the insulating layer 12 (SiNx film), and the mask has multiple holes. The places where the grooves 126 are to be formed on the insulating layer 12 (SiNx film) are exposed through these holes, and other places are covered by the mask; the insulating layer 12 exposed through these holes is etched by gas plasma, so as to form multiple grooves 126 arranged at intervals on the insulating layer 12, and finally the mask is removed. The shape of the groove 126 is not limited, and the thickness of the groove 126 is 1 nm to 100 nm. Preferably, the thickness of the groove 126 is 10 nm, 20 nm, 30 nm, 40 nm or 50 nm. Since the groove 126 is formed by etching on the insulating layer 12, the thickness of the groove 126 is thinner, thereby ensuring that the thickness of the sample pool is thin enough to allow electrons to pass through, or transparent to electrons. In a specific embodiment, the thickness of the groove 126 is 50 nm, and the diameter of the groove is 3 μm.

In step S5, the carbon nanotube layer 16 comprises at least one layer of super-aligned carbon nanotube film, which is a carbon nanotube film obtained by pulling from a carbon nanotube array. Please refer to FIG. 2, the super-aligned carbon nanotube film comprises a plurality of carbon nanotubes preferentially oriented in the same direction and arranged parallel to the surface of the super-aligned carbon nanotube film, and the carbon nanotubes are connected end to end by van der Waals forces. When the carbon nanotube layer 16 comprise multiple layers of super-aligned carbon nanotube film, the multiple layers of super-aligned carbon nanotube film are stacked on each other, and a cross angle α is formed between the preferentially oriented carbon nanotubes in two adjacent layers of super-aligned carbon nanotube film, and α is greater than or equal to 0 degrees and less than or equal to 90 degrees (0°≤α≤90°).

Specifically, a layer of the super-aligned carbon nanotube film is laid on the surface of the insulating layer 12 away from the substrate 10, and then another layer of the super-aligned carbon nanotube film is laid on the super-aligned carbon nanotube film, so that the extension directions of the carbon nanotubes preferentially oriented in the two layers of super-aligned carbon nanotube films are perpendicular to each other, forming a carbon nanotube layer 16, and the carbon nanotube layer 16 covers the window. Then, the other carbon nanotube layers 16 except the window are removed, so that the first electrode 141, the second electrode 142, the third electrode 143, the fourth electrode 144, the fifth electrode 145, the sixth electrode 146 and the seventh electrode 148 are exposed, and the carbon nanotube layer 16 located at the window is cut into the first carbon nanotube layer 162 and the second carbon nanotube layer 164, and the first carbon nanotube layer 162 and the second carbon nanotube layer 164 are arranged side by side with an interval, and the metal thermometer is exposed between the first carbon nanotube layer 162 and the second carbon nanotube layer 164. The first electrode 141 is located on the side of the first carbon nanotube layer 162 away from the sample pool and is electrically connected to the first carbon nanotube layer 162. The second electrode 142 is located on the side of the second carbon nanotube layer 164 away from the sample pool and is electrically connected to the second carbon nanotube layer 164. The third electrode 143 and the fourth electrode 144 are located on the side of the first electrode 141 away from the first carbon nanotube layer 162, and one end of the third electrode 143 and the fourth electrode 144 are electrically connected to the metal thermometer respectively. The fifth electrode 145 and the sixth electrode 146 are located on the side of the second electrode 142 away from the second carbon nanotube layer 164, and one end of the fifth electrode 145 and the sixth electrode 146 are electrically connected to the metal thermometer respectively. One end of the seventh electrode 148 is electrically connected to the first carbon nanotube layer 162, and the other end is electrically connected to the second carbon nanotube layer 164. The seventh electrode 148 connects the first carbon nanotube layer 162 and the second carbon nanotube layer 164 in series.

In a specific embodiment, the SACNT film is patterned into two pieces on the SiNx window using photolithography and reactive ion etching (RIE), namely the first carbon nanotube layer 162 and the second carbon nanotube layer 164. The method of removing the other carbon nanotube layers 16 except the window is not limited.

In a specific embodiment, the method of first patterning photolithography and then gas plasma etching is used to remove the other carbon nanotube layers 16 except the window. Specifically, a mask is covered on the carbon nanotube layer 16, the mask has a through hole, and the other carbon nanotube layers 16 except the window are exposed through the through hole. The carbon nanotube layer 16 exposed through the hole is etched and removed by gas plasma, and finally the mask is removed.

The following uses a specific embodiment to illustrate the preparation method of the carbon nanotube micro-heating chip 100, but is not limited to this.

Please refer to FIG. 10, the substrate 10 is a silicon wafer having a layer of SiO2 on both surfaces, and then a SiNₓ film is disposed on each layer of SiO2, thereby forming a five-layer structure of SiNₓ (thickness 200 nm)/SiO2 (thickness 200 nm)/Si (thickness 400 μm)/SiO2 (thickness 200 nm)/SiNₓ (thickness 200 nm). Then, a patterned 5 nm/50 nm Cr/Pt electrode is deposited on the top SiNₓ film by electron beam evaporation to form seven electrode pads from the first electrode 141 to the seventh electrode 148, and a platinum metal layer is deposited between the first electrode 141 and the second electrode 142 to form a platinum thermometer. Then, from the bottom SiNₓ film upward, by photolithography and gas plasma etching (the gas is CF₄, the gas flow rate is 40 sccm, the pressure is 2 Pa, the power is 50 W, and the etching time is 5.5 min), the SiO2/SiNₓ layer under the silicon wafer in the five-layer structure SiNₓ/SiO₂/Si/SiO₂/SiNₓ is etched to form a square opening, and a part of the silicon wafer is exposed. The silicon wafer is etched with KOH solvent, and the silicon wafer and the SiO2 film on the silicon wafer are also etched to form a through hole 106. That is, the other four layers except the top SiNₓ film in the five-layer structure SiNₓ/SiO₂/Si/SiO₂/SiNₓ are etched to form a through hole 106, and the top SiNₓ film is suspended at the through hole 106, thereby forming a square window. The area of the suspended SiNₓ film at the through hole 106 is 730 μm×730 μm, and the thickness is 200 nm. In order to ensure that the sample cell is thin enough to allow electrons to pass through, a sample pool with a diameter of 3 μm and a thickness of 50 nm was fabricated by photolithography and dry etching (the gas was CF₄, the gas flow was 40 sccm, the pressure was 2 Pa, the power was 50 W, and the etching time was 4.5 min) on SiNₓ membrane, thereby ensuring high electron transparency under TEM. Then a carbon nanotube layer is formed on the top SiNₓ film. Using photolithography and RIE (gas is O₂, gas flow is 40 sccm, pressure is 2 Pa, power is 40 W, etching time is 2 min), the carbon nanotube layer is cut into two pieces, exposing the sample pool and the metal thermometer, and the other carbon nanotube layers except the carbon nanotube layer at the square window are etched away to expose the seven electrode pads. In this way, a carbon nanotube micro-heating chip 100 is obtained. In addition, multiple carbon nanotube micro-heating chips 100 can be directly formed on a 4-inch wafer at the same time to form a wafer-level carbon nanotube micro-heating chip 100. Then cut with a diamond saw to obtain a single carbon nanotube micro-heating chip 100.

The carbon nanotube micro-heating chip and the preparation method thereof have the following advantages: first, the carbon nanotube micro-heating chip has a fast response speed and can be heated to 800° C. within 16 ms, with a corresponding power consumption of 0.068 mW/1000 μm². The fast response speed is due to the ultra-small heat capacity per unit area of CNT, and the efficient heating can be attributed to the conductive CNT network with nanometer thickness; second, the expansion or deformation of the sample pool in the carbon nanotube micro-heating chip is very small, and its bulge suppression at 800° C. is only 100 nm. The obvious reduction of the bulge effect is due to the weak van der Waals interaction between CNT and SiNₓ film; third, the carbon nanotube micro-heating chip can dynamically observe the sample during TEM characterization, which proves that the carbon nanotube micro-heating chip can be actually used to explore thermodynamic processes; fourth, the preparation method of the carbon nanotube micro-heating chip is simple, and the carbon nanotube micro-heating chip can be prepared on a large scale.

It is to be understood that the above-described embodiments are intended to illustrate rather than limit the present disclosure. Variations can be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

Depending on the embodiment, certain of the steps of a method described can be removed, others can be added, and the sequence of steps can be altered. The description and the claims drawn to a method may comprise some indication in reference to certain steps. However, the indication used is only to be viewed for identification purposes and not as a suggestion as to an order for the steps.

What is claimed is:

1. A carbon nanotube micro-heating chip, comprising:
a substrate comprising a first surface and a second surface opposite to each other, wherein the substrate defines a through hole penetrating through the first surface and the second surface;
an insulating layer, wherein the insulating layer is located on the first surface of the substrate, and a window is formed by suspending the insulating layer over the through hole, and a plurality of grooves are defined in the window to form a sample pool configured to receive a sample;
a first carbon nanotube layer and a second carbon nanotube layer, wherein the first carbon nanotube layer and the second carbon nanotube layer are arranged at intervals in the window and exposed out from the sample pool; and
a metal thermometer, wherein the metal thermometer is arranged in the window between the first carbon nanotube layer and the second carbon nanotube layer, and the first carbon nanotube layer and the second carbon nanotube layer are configured to heat the sample in the sample pool, and the metal thermometer is configured to measure a temperature of a heated area.

2. The carbon nanotube micro-heating chip of claim 1, wherein each of the first carbon nanotube layer and the second carbo nanotube layer comprises at least one super-aligned carbon nanotube film.

3. The carbon nanotube micro-heating chip of claim 2, wherein the at least one super-aligned carbon nanotube film comprises a plurality of carbon nanotubes oriented substantially in an orientation direction, and the plurality of carbon nanotubes are connected with each other end to end by van der Waals forces.

4. The carbon nanotube micro-heating chip of claim 3, wherein the at least one carbon nanotube film comprises a plurality of super-aligned carbon nanotube films.

5. The carbon nanotube micro-heating chip of claim 4, wherein the orientation direction of the o plurality of carbon nanotubes in a super-aligned carbon nanotube film of the plurality of super-aligned carbon nanotube films and the orientation direction of the plurality of carbon nanotubes in an adjacent super-aligned carbon nanotube film of the plurality layers of super-aligned carbon nanotube films define a crossing angle α, α is greater than or equal to zero (0) degrees and less than or equal to 90 degrees.

6. The carbon nanotube micro-heating chip of claim 3, wherein one of the first carbon nanotube layer and the second carbon nanotube layer comprises two super-aligned carbon nanotube films, and the orientation direction of the carbon nanotubes in one of the two super-aligned carbon nanotube films is perpendicular to the orientation direction of another one of the two super-aligned carbon nanotube films.

7. The carbon nanotube micro-heating chip of claim 1, further comprising a first electrode, a second electrode, a third electrode, a fourth electrode, a fifth electrode, a sixth electrode and a seventh electrode, the first electrode is electrically connected to the first carbon nanotube layer, the second electrode is electrically connected to the second carbon nanotube layer, each of the third electrode, the fourth electrode, the fifth electrode and the sixth electrode are electrically connected to the metal thermometer, and the seventh electrode electrically connects the first carbon nanotube layer and the second carbon nanotube layer.

8. The carbon nanotube micro-heating chip of claim 1, wherein a material of the insulating layer is silicon nitride or silicon carbide.

9. The carbon nanotube micro-heating chip of claim 1, wherein a thickness of the insulating layer at a bottom of each of the plurality of grooves ranges from 1 nm to 100 nm.

10. A method to prepare a carbon nanotube micro-heating chip, the method comprising:
S1, providing a substrate comprising a first surface and a second surface;
S2, applying an insulating layer on the first surface;
S3, setting seven electrodes and a metal thermometer on a surface of the insulating layer away from the substrate, the seven electrodes comprises a first electrode, a second electrode, a third electrode, a fourth electrode, a fifth electrode, a sixth electrode and a seventh electrode, one end of the third electrode and one end of the fourth electrode are respectively electrically connected to the metal thermometer, and one end of the fifth electrode and one end of the sixth electrode are respectively electrically connected to the metal thermometer;
S4: forming a thorough hole in the substrate penetrating through the first surface and the second surface, forming a widow by suspending the insulating layer overs the through hole;
S5, forming a plurality of grooves in the window as a sample pool configured for carrying samples, covering a first carbon nanotube layer and a second carbon nanotube layer on the window, and arranging the plurality of grooves between the first carbon nanotube layer and the second carbon nanotube layer, electrically connecting the first carbon nanotube layer and the second carbon nanotube layer via the seventh electrode, electrically connecting the first electrode to the first carbon nanotube layer, and electrically connecting the second electrode to the second carbon nanotube layer.

11. The method of claim 10, wherein in S5, covering the first carbon nanotube layer and the second carbon nanotube layer on the window comprising layering a plurality of super-aligned carbon nanotube films sequentially on the window.

12. The method of claim 10, further comprising providing the plurality of super-aligned carbon nanotube films comprising a plurality of carbon nanotubes oriented substantially in an orientation direction, and connected with each end to end by van der Waals forces.
